(19) United States
(12) Patent Application Publication
(10) Pub. No.: US 2026/0239981 A1
(43) Pub. Date: Aug. 13, 2026

(54) COLD PLATE AND ELECTRONIC DEVICE

(71) Applicant: Wiwynn Corporation, New Taipei City (TW)

(72) Inventors: Tsung-Yi Chen, New Taipei City (TW); Hao-Jhan Hong, New Taipei City (TW); Yi Cheng, New Taipei City (TW); WEN AN CHEN, New Taipei City (TW)

(21) Appl. No.: 19/317,428

(22) Filed: Sep. 3, 2025

(30) Foreign Application Priority Data
Feb. 12, 2025 (TW) 114105175

(51) Int. Cl. H10W 40/73; H05K 1/02; H05K 7/20; H10W 78/00; H10W 72/00; H10W 72/30; H10W 90/00

(52) U.S. Cl. CPC H10W 40/73; H05K 1/0203; H05K 7/20327; H10W 78/00; H10W 72/07354; H10W 72/342; H10W 90/734

(57) ABSTRACT

A cold plate is configured to be thermally coupled to a heat source of a motherboard via a thermal interface material. The cold plate has an inlet channel, a heat exchange chamber, a peripheral channel and an outlet channel. The heat exchange chamber communicates with the inlet channel. The peripheral channel communicates with the inlet channel and surrounds heat exchange chamber. The outlet channel communicates with the heat exchange chamber and the peripheral channel.

### CROSS-REFERENCE TO RELATED APPLICATIONS

This non-provisional application claims priority under 35 U.S.C. § 119(a) on Patent Application No(s). 114105175 filed in Taiwan, R.O.C. on Feb. 12, 2025, the entire contents of which are hereby incorporated by reference.

### Technical Field

The disclosure relates to a cold plate and an electronic device.

### BACKGROUND

Liquid metal is an emerging thermal interface material in recent years, known for its relatively high thermal conductivity. Due to high conductivity and fluidity of the liquid metal, if proper protective measures are not in place, the liquid metal may flow from a chip and comes into contact surrounding electronic components, causing damage.

To prevent the flowing of liquid metal, a common solution is to apply resin around the chip. This not only protects the surrounding components but also forms a barrier that can prevent the liquid metal from flowing out of the chip area. Then, by installing a heat dissipation module, the liquid metal can be sealed between the chip and the heat dissipation module.

Although the resin barrier can reduce the possibility of the flowing of the liquid metal to the surrounding components, if the surface smoothness of the resin barrier is reduced due to uneven surfaces around the chip during the coating of the resin barrier, it may result in insufficient sealing between the resin barrier and the heat dissipation module, allowing the liquid metal to pass through small gaps. In light of this, how to solve the aforementioned issue is one of the topics in this field.

### SUMMARY

One embodiment of the disclosure provides a cold plate. The cold plate is configured to be thermally coupled to a heat source of a motherboard via a thermal interface material. The cold plate has an inlet channel, a heat exchange chamber, a peripheral channel and an outlet channel. The heat exchange chamber communicates with the inlet channel. The peripheral channel communicates with the inlet channel and surrounds heat exchange chamber. The outlet channel communicates with the heat exchange chamber and the peripheral channel.

Another embodiment of the disclosure provides an electronic device. The electronic device includes a motherboard module. The motherboard module includes a motherboard, a thermal interface material and a cold plate. The motherboard includes a circuit board and a heat source disposed on the circuit board. The cold plate is thermally coupled to the heat source of the motherboard via the thermal interface material. The cold plate has an inlet channel, a heat exchange chamber, a peripheral channel and an outlet channel. The heat exchange chamber communicates with the inlet channel. The peripheral channel communicates with the inlet channel and surrounds the heat exchange chamber. The outlet channel communicates with the heat exchange chamber and the peripheral channel.

According to the cold plate and the electronic device as discussed in the above embodiments, both of the heat exchange chamber and the peripheral channel of the cold plate communicate with the inlet channel and the outlet channel, and the peripheral channel surrounds the heat exchange chamber. By this configuration, the low-temperature working fluid entering the cold plate from the inlet channel flows in the peripheral channel. As a result, the thermal interface material on the outer side solidifies into the solid state when it flows to the portion of the cold plate where the peripheral channel is located, forming a barrier to prevent the thermal interface material on the inner side from continuing to flow outward. This ensures that the thermal interface material does not contact electronic components around the heat source.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a partial cross-section view of an electronic device according to some embodiments of the disclosure;

FIG. 2 is a partial cross-section view of a motherboard module according to some embodiments of the disclosure;

FIG. 3 is a top view of a cold plate according to some embodiments of the disclosure;

FIG. 4 shows a cold plate is placed on a motherboard of a motherboard module according to some embodiments of the disclosure; and

FIG. 5 shows a thermal interface material flows after a cold plate placed on a motherboard is pressed downward according to some embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

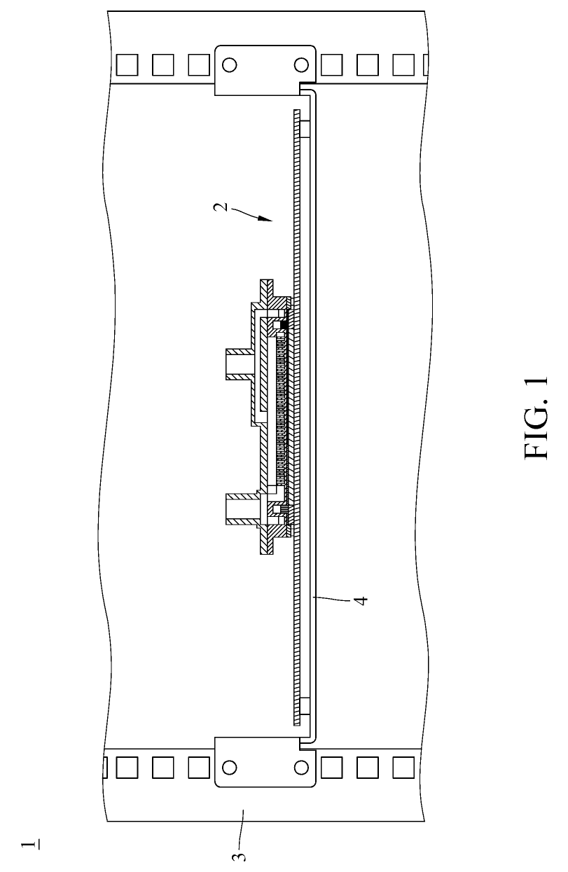

Referring to FIG. 1, FIG. 1 is a partial cross-section view of an electronic device 1 according to some embodiments of the disclosure. The structural features of FIG. 1 can be applied to other embodiments of the disclosure.

The electronic device 1 includes a motherboard module 2. In some embodiments, the electronic device 1 may further include a rack 3 and a support component 4. The support component 4 is, for example, a tray or a bracket. The motherboard module 2 is configured to be mounted in the rack 3 via the support component 4, but the disclosure is not limited thereto. In some other embodiments, the motherboard module may be mounted in other types of accommodation devices.

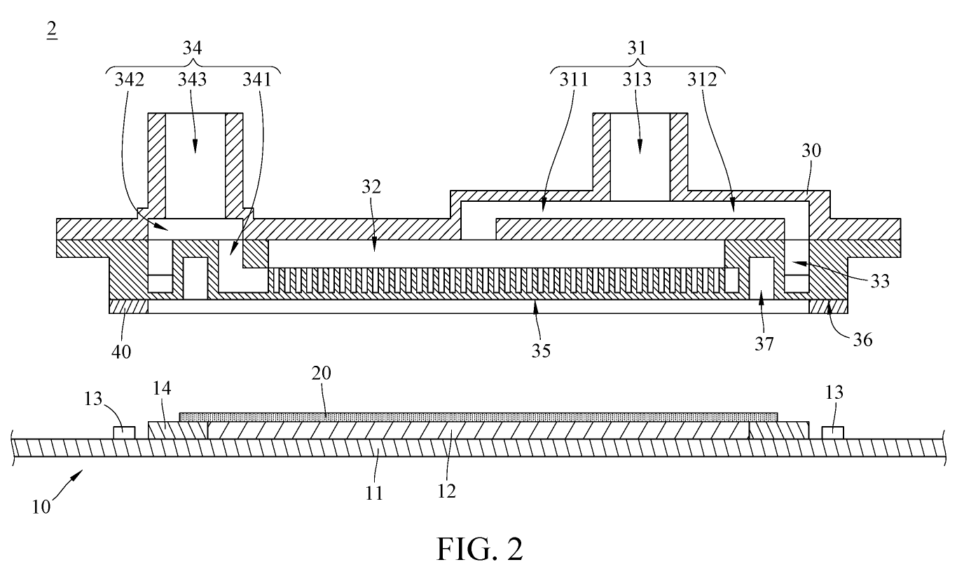

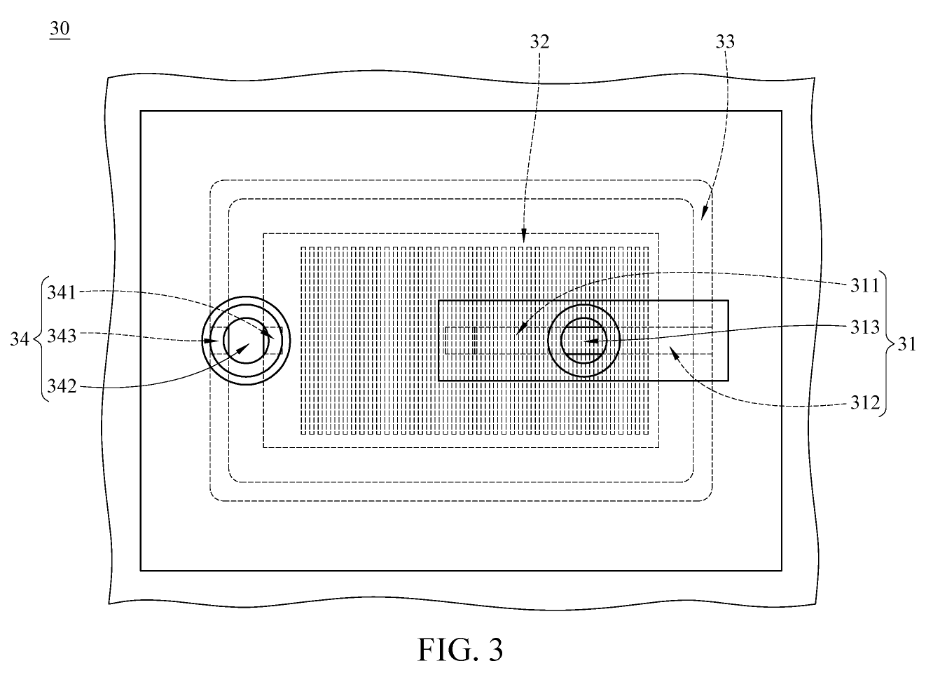

Referring to FIGS. 2 and 3, FIG. 2 is a partial cross-section view of the motherboard module 2 according to some embodiments of the disclosure, and FIG. 3 is a top view of a cold plate 30 according to some embodiments of the disclosure. The structural features of FIGS. 2 and 3 can be applied to other embodiments of the disclosure.

The motherboard module 2 includes a motherboard 10, a thermal interface material 20 and a cold plate 30. The motherboard 10 includes a circuit board 11 and a heat source 12. The heat source 12 is disposed on the circuit board 11. The cold plate 30 is thermally coupled to the heat source 12 of the motherboard 10 via the thermal interface material 20. The cold plate 30 has an inlet channel 31, a heat exchange chamber 32, a peripheral channel 33 and an outlet channel 34. The heat exchange chamber 32 communicates with the inlet channel 31. The peripheral channel 33 communicates with the inlet channel 31 and surrounds the heat exchange chamber 32. The outlet channel 34 communicates with the heat exchange chamber 32 and the peripheral channel 33. In other words, an upstream and a downstream of the peripheral channel 33 are the inlet channel 31 and the outlet channel 34, respectively. Moreover, an upstream and a downstream of the heat exchange chamber 32 are the inlet channel 31 and the outlet channel 34, respectively.

In some embodiments, the thermal interface material 20 may be a metal that can undergo a phase change between a liquid state and a solid state, and has high thermal conductivity and electrical conductivity.

In some embodiments, the heat source 12 of the motherboard 10 may be a central processing unit (CPU) or a graphics processing unit (GPU). In some embodiments, the motherboard 10 may further include a plurality of on-board components 13. The on-board components 13 are disposed on the circuit board 11 and located around the heat source 12. The on-board components 13 may be electronic components other than the central processing unit or the graphics processing unit, such as capacitors.

In some embodiments, the cold plate 30 further has a thermally coupling surface 35 and a contact surface 36. The thermally coupling surface 35 corresponds to (e.g., faces away from) the heat exchange chamber 32, and the thermally coupling surface 35 is configured to be thermally coupled to the heat source 12 of the motherboard 10 via the thermal interface material 20. The contact surface 36 is located around the thermally coupling surface 35 and corresponds to (e.g., faces away from) the peripheral channel 33. The contact surface 36 is configured to correspond to the on-board components 13 of the motherboard 10.

In some embodiments, the thermally coupling surface 35 and the contact surface 36 of the cold plate 30 are coplanar, but the disclosure is not limited thereto. In some other embodiments, the thermally coupling surface and the contact surface may not be coplanar.

In some embodiments, the cold plate 30 has a groove 37. The groove 37 separates the peripheral channel 33 and the heat exchange chamber 32. The groove 37 is configured to accommodate a part of the thermal interface material 20. In some embodiments, the groove 37 is in an annular shape, but the disclosure is not limited thereto. In some other embodiments, the groove may not be in the annular shape, the number of grooves may be multiple, and these grooves may be annularly arranged.

In some embodiments, the motherboard module 2 further includes an annular insulation component 40. The motherboard module 2 is disposed between the on-board components 13 and the contact surface 36 of the cold plate 30 and is configured to stop the thermal interface material 20. In some embodiments, the annular insulation component 40 is elastic, and the annular insulation component 40 may be, for example, made of resin. In some embodiments, before the cold plate 30 is assembled onto the motherboard 10, the annular insulation component 40 may be pre-installed on the contact surface 36 of the cold plate 30 or on the on-board components 13 of the motherboard 10.

In some embodiments, the motherboard 10 further includes an annular frame 14. The annular frame 14 is disposed on the circuit board 11 and contacts the outer edge of the heat source 12. An orthogonal projection of the groove 37 is entirely located on the annular frame 14. That is, the groove 37 is located directly above the annular frame 14. The annular frame 14 contacts the annular insulation component 40. In some embodiments, different sides of the annular insulation component 40 contact the on-board components 13, the contact surface 36 and the annular frame 14, respectively. In some embodiments, the orthogonal projection of the groove 37 is arranged to surround an outer boundary of the heat source 12. In the embodiment shown in FIG. 2, the orthogonal projection of the groove 37 is arranged entirely offsetting a top surface of the heat source 12.

In some embodiments, the peripheral channel 33 of the cold plate 30 does not directly communicate with the heat exchange chamber 32. In some embodiments, the inlet channel 31 of the cold plate 30 has a first branch portion 311 and a second branch portion 312. The first branch portion 311 communicates with the heat exchange chamber 32, and the second branch portion 312 communicates with the peripheral channel 33. In some embodiments, the inlet channel 31 of the cold plate 30 further includes a main inlet portion 313. The first branch portion 311 further communicates with the main inlet portion 313, and the second branch portion 312 further communicates with the main inlet portion 313. In some embodiments, the outlet channel 34 of the cold plate 30 has a first outflow portion 341 and a second outflow portion 342. The first outflow portion 341 communicates with the heat exchange chamber 32, and the second outflow portion 342 communicates with the peripheral channel 33. In some embodiments, the outlet channel 34 of the cold plate 30 further includes a convergent portion 343. The first outflow portion 341 further communicates with the convergent portion 343, and the second outflow portion 342 further communicates with the convergent portion 343.

Next, the process of assembling the cold plate 30 onto the motherboard 10 will be described. First, as shown in FIG. 2, the thermal interface material 20 is placed on the heat source 12 and the annular frame 14, where the thermal interface material 20 may be in either the liquid state or the solid state at this moment.

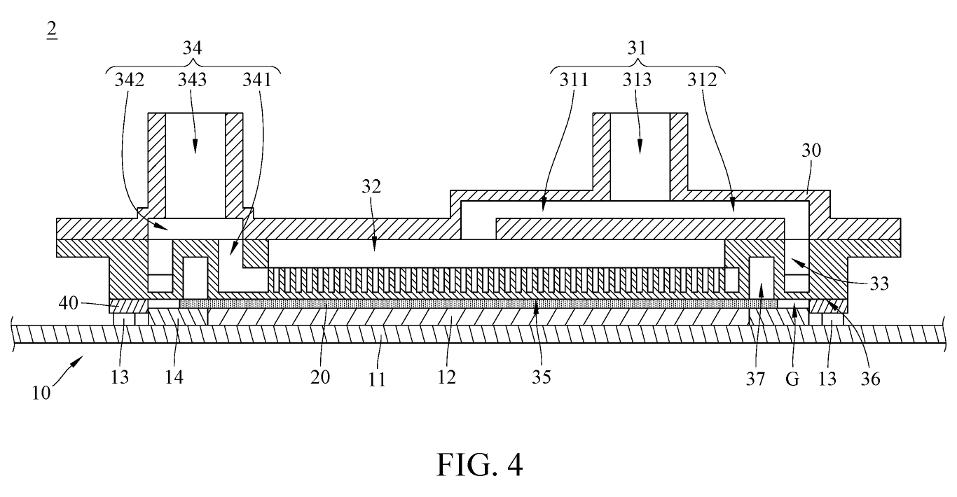

Then, referring to FIG. 4, FIG. 4 shows the cold plate 30 is placed on the motherboard 10 of the motherboard module 2 according to some embodiments of the disclosure. The structural features of FIG. 4 can be applied to other embodiments of the disclosure. As shown in FIG. 4, the cold plate 30 is placed on the motherboard 10, such that the thermally coupling surface 35 of the cold plate 30 contacts one side of the thermal interface material 20 located away from the heat source 12, and the different sides of the annular insulation component 40 contact the contact surface 36 of the cold plate 30, the annular frame 14, and the on-board components 13, respectively. At this moment, the cold plate 30 is in an uncompressed state, and the thermal interface material 20 in the liquid or solid state, is not under pressure, maintaining a distance from the annular insulation component 40 and thus forming a gap G therebetween. If the thermal interface material 20 is in the solid state at this moment, the thermal interface material 20 is then heated to become the liquid state.

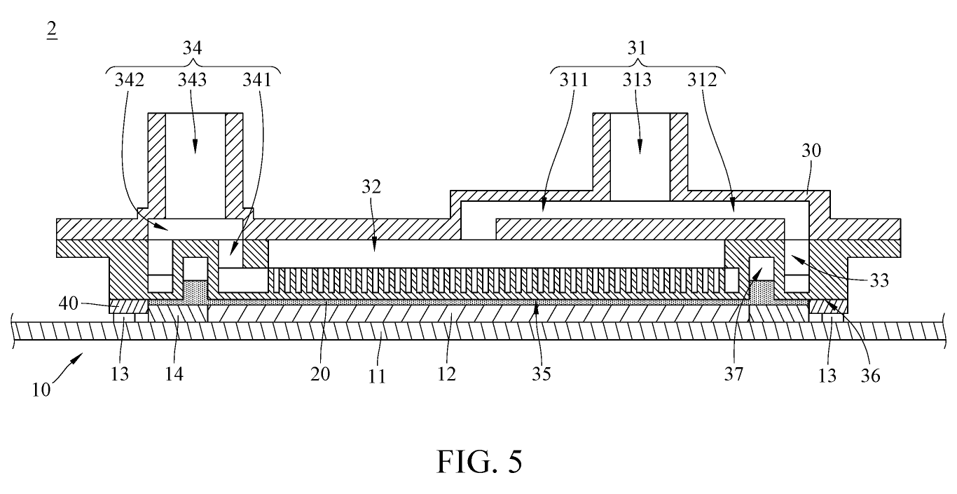

Then, referring to FIG. 5, FIG. 5 shows the thermal interface material 20 flows after the cold plate 30 placed on the motherboard 10 is pressed downward according to some embodiments of the disclosure. The structural features of FIG. 5 can be applied to other embodiments of the disclosure. As shown in FIG. 5, an external force is applied to the cold plate 30 in a direction towards the heat source 12, causing the cold plate 30 to move and switch from the uncompressed state to a compressed state. At this moment, a part of the liquid thermal interface material 20 flows outward into the gap G and onto the contact surface 36 of the cold plate 30 facing away from the peripheral channel 33. Another part of the liquid thermal interface material 20 flows into the groove 37 of the cold plate 30, while the annular insulation component 40 prevents the thermal interface material 20 from flowing further. Thus, the process of assembling the cold plate 30 onto the motherboard 10 is completed.

In the above embodiment, both of the heat exchange chamber 32 and the peripheral channel 33 of the cold plate 30 communicate with the inlet channel 31 and the outlet channel 34, and the peripheral channel 33 surrounds the heat exchange chamber 32. By this configuration, a low-temperature working fluid entering the cold plate 30 from the inlet channel 31 flows in the peripheral channel 33. As a result, the thermal interface material 20 on the outer side solidifies into the solid state when it flows to the portion of the cold plate 30 where the peripheral channel 33 is located, forming a barrier to prevent the thermal interface material 20 on the inner side from continuing to flow outward. This ensures that the thermal interface material 20 does not contact the on-board components 13 around the heat source 12.

Furthermore, in the above embodiments, the main inlet portion 313 of the inlet channel 31 communicates with the heat exchange chamber 32 and the peripheral channel 33 through the first branch portion 311 and the second branch portion 312. The heat exchange chamber 32 and the peripheral channel 33 respectively communicate with the convergent portion 343 through the first outflow portion 341 and the second outflow portion 342 of the outlet channel 34. By this configuration, the heat exchange chamber 32 and the peripheral channel 33 are connected in parallel, which ensures that the working fluid entering the peripheral channel 33 does not absorb heat from the heat source 12, thereby keeping the working fluid in the peripheral channel 33 at a low temperature to effectively solidify the thermal interface material 20.

It should be noted that the heat exchange chamber 32 and the peripheral channel 33 are not limited to being connected in parallel. In some other embodiments, the heat exchange chamber and the peripheral channel may be connected in series, and the inlet channel, the peripheral channel, the heat exchange chamber and the outlet channel may be connected sequentially (e.g., from upstream to downstream). In some another embodiment, the heat exchange chamber and the peripheral channel may be independent from each other, with no communication between them. That is, the cold plate may not have a main inlet portion and a convergent portion, moreover, a path formed by the first branch portion, the heat exchange chamber and the first outflow portion may be independent from a path formed by the second branch portion, the peripheral channel and the second outflow portion.

In the above embodiment, the orthogonal projection of the groove 37 is entirely located on the annular frame 14, which ensures that the position of the groove 37 does not sacrifice the contact area between the thermally coupling surface 35 of the cold plate 30 and the heat source 12, thereby maintaining the heat exchange efficiency between the heat source 12 and the cold plate 30.

It should be noted that the orthogonal projection of the groove 37 is not limited to being entirely located on the annular frame 14. In some other embodiments, if the arrangement of the groove does not excessively affect the heat exchange efficiency between the heat source and the cold plate, the orthogonal projection of the groove may be partially or entirely located on the heat source. In other words, the orthogonal projection of the groove may be partially located on the annular frame, or the orthogonal projection of the groove may not be located on the annular frame at all. On the other hand, the annular frame 14 is an optional component and may be omitted in some other embodiments.

In some embodiments, the groove 37 of the cold plate 30 separates the peripheral channel 33 and the heat exchange chamber 32, which not only accommodates a part of the thermal interface material 20, but also reduces the heat exchange between the heat exchange chamber 32 and the peripheral channel 33. This helps further ensure that the working fluid in the peripheral channel 33 remains sufficiently low in temperature to solidify the thermal interface material 20. It should be noted that the groove 37 is an optional structure and may be omitted in some other embodiments.

In the above embodiments, the different sides of the annular insulation component 40 that respectively contact the contact surface 36 of the cold plate 30, the annular frame 14, and the on-board components 13, which further isolate the thermal interface material 20 from the on-board components 13. It should be noted that the annular insulation component 40 is an optional component and may be omitted in some other embodiments.

According to the cold plate and the electronic device as discussed in the above embodiments, both of the heat exchange chamber and the peripheral channel of the cold plate communicate with the inlet channel and the outlet channel, and the peripheral channel surrounds the heat exchange chamber. By this configuration, the low-temperature working fluid entering the cold plate from the inlet channel flows in the peripheral channel. As a result, the thermal interface material on the outer side solidifies into the solid state when it flows to the portion of the cold plate where the peripheral channel is located, forming a barrier to prevent the thermal interface material on the inner side from continuing to flow outward. This ensures that the thermal interface material does not contact the on-board components 13 around the heat source.

Furthermore, the main inlet portion of the inlet channel communicates with the heat exchange chamber and the peripheral channel through the first branch portion and the second branch portion, and the heat exchange chamber and the peripheral channel respectively communicate with the convergent portion through the first outflow portion and the second outflow portion of the outlet channel. By this configuration, the heat exchange chamber and the peripheral channel are connected in parallel, which ensures that the working fluid entering the peripheral channel does not absorb heat from the heat source, thereby keeping the working fluid in the peripheral channel at a low temperature to solidify the thermal interface material.

Moreover, the groove of the cold plate separates the peripheral channel and the heat exchange chamber, which not only accommodates a part of the thermal interface material, but also reduces the heat exchange between the heat exchange chamber and the peripheral channel. This helps further ensure that the working fluid in the peripheral channel remains sufficiently low in temperature to solidify the thermal interface material.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A cold plate, configured to be thermally coupled to a heat source of a motherboard via a thermal interface material, the cold plate having:
an inlet channel;
a heat exchange chamber, communicating with the inlet channel;
a peripheral channel, communicating with the inlet channel and surrounding heat exchange chamber; and
an outlet channel, communicating with the heat exchange chamber and the peripheral channel.

2. The cold plate according to claim 1, wherein the cold plate has a thermally coupling surface and a contact surface, the thermally coupling surface corresponds to the heat exchange chamber, the thermally coupling surface is configured to be thermally coupled to the heat source of the motherboard via the thermal interface material, the contact surface is located around the thermally coupling surface and corresponds to the peripheral channel, and the contact surface is configured to correspond to a plurality of on-board components of the motherboard.

3. The cold plate according to claim 1, wherein the cold plate further has a groove, the groove separates the peripheral channel and the heat exchange chamber, and the groove is configured to accommodate a part of the thermal interface material.

4. The cold plate according to claim 3, wherein the groove is in an annular shape.

5. The cold plate according to claim 2, wherein the thermally coupling surface is coplanar with the contact surface.

6. The cold plate according to claim 1, wherein the inlet channel of the cold plate has a first branch portion and a second branch portion, the first branch portion communicates with the heat exchange chamber, and the second branch portion communicates with the peripheral channel.

7. The cold plate according to claim 1, wherein the outlet channel of the cold plate has a first outflow portion and a second outflow portion, the first outflow portion communicates with the heat exchange chamber, and the second outflow portion communicates with the peripheral channel.

8. The cold plate according to claim 6, wherein the inlet channel of the cold plate further has a main inlet portion, the first branch portion further communicates with the main inlet portion, and the second branch portion further communicates with the main inlet portion.

9. The cold plate according to claim 7, wherein the outlet channel of the cold plate further has a convergent portion, the first outflow portion further communicates with the convergent portion, and the second outflow portion further communicates with the convergent portion.

10. The cold plate according to claim 1, wherein the peripheral channel does not directly communicate with the heat exchange chamber.

11. The cold plate according to claim 1, wherein an upstream and a downstream of the peripheral channel are the inlet channel and the outlet channel, respectively.

12. An electronic device, comprising:
a motherboard module, comprising:
a motherboard, comprising a circuit board and a heat source disposed on the circuit board;
a thermal interface material; and
a cold plate, thermally coupled to the heat source of the motherboard via the thermal interface material, wherein the cold plate has:
an inlet channel;
a heat exchange chamber, communicating with the inlet channel;
a peripheral channel, communicating with the inlet channel and surrounding the heat exchange chamber; and
an outlet channel, communicating with the heat exchange chamber and the peripheral channel.

13. The electronic device according to claim 12, wherein the cold plate has a groove, the groove separates the peripheral channel and the heat exchange chamber, and the groove is configured to accommodate a part of the thermal interface material.

14. The electronic device according to claim 13, wherein the motherboard module further comprises an annular insulation component, the motherboard further comprises a plurality of on-board components, the plurality of on-board components are located around the heat source, the cold plate has a contact surface, the contact surface corresponds to the peripheral channel, and the annular insulation component is disposed between the plurality of on-board components and the contact surface and is configured to stop the thermal interface material.

15. The electronic device according to claim 14, wherein the annular insulation component is elastic.

16. The electronic device according to claim 14, wherein the motherboard further comprises an annular frame, the annular frame is disposed on the circuit board and contacts an outer edge of the heat source, an orthogonal projection of the groove is entirely located on the annular frame, and the annular frame contacts the annular insulation component.

17. The electronic device according to claim 16, wherein different sides of the annular insulation component respectively contact the plurality of on-board components, the contact surface and the annular frame.

18. The electronic device according to claim 13, wherein the groove is in an annular shape.

19. The electronic device according to claim 12, wherein the cold plate has a thermally coupling surface and a contact surface, the thermally coupling surface corresponds to the heat exchange chamber, the thermally coupling surface is configured to be thermally coupled to the heat source of the motherboard via the thermal interface material, the contact surface is located around the thermally coupling surface and corresponds to the peripheral channel, and the contact surface is configured to correspond to a plurality of on-board components of the motherboard.

20. The electronic device according to claim 19, wherein the thermally coupling surface is coplanar with the contact surface.

21. The electronic device according to claim 12, wherein the inlet channel of the cold plate has a first branch portion and a second branch portion, the first branch portion communicates with the heat exchange chamber, and the second branch portion communicates with the peripheral channel.

22. The electronic device according to claim 12, wherein the outlet channel of the cold plate has a first outflow portion and a second outflow portion, the first outflow portion communicates with the heat exchange chamber, and the second outflow portion communicates with the peripheral channel.

23. The electronic device according to claim 21, wherein the inlet channel of the cold plate further has a main inlet portion, the first branch portion further communicates with the main inlet portion, and the second branch portion further communicates with the main inlet portion.

24. The electronic device according to claim 22, wherein the outlet channel of the cold plate further has a convergent portion, the first outflow portion further communicates with the convergent portion, and the second outflow portion further communicates with the convergent portion.

25. The electronic device according to claim 12, wherein the peripheral channel does not directly communicate with the heat exchange chamber.

26. The electronic device according to claim 12, further comprising a rack, wherein the motherboard module is configured to be mounted in the rack.

27. The electronic device according to claim 12, wherein an upstream and a downstream of the peripheral channel are the inlet channel and the outlet channel, respectively.
